(19) United States
(12) Patent Application Publication
(10) Pub. No.: US 2012/0315734 A1
(43) Pub. Date: Dec. 13, 2012

(54) METHOD FOR FABRICATING SEMICONDUCTOR DEVICE

(76) Inventors: Chan-Lon Yang, Taipei City (TW); Ger-Pin Lin, New Taipei City (TW); Tsuo-Wen Lu, Kaohsiung City (TW)

(21) Appl. No.: 13/156,345

(22) Filed: Jun. 9, 2011

(51) Int. Cl. H01L 21/8238; H01L 21/336

(52) U.S. Cl. 438/230; 438/299; 257/E21.409; 257/E21.632

(57) ABSTRACT

A method for fabricating semiconductor device is disclosed. The method includes the steps of: providing a substrate, wherein the substrate comprises a gate structure thereon; forming an offset spacer on the sidewall of the gate structure; forming a cap layer to cover the substrate and the gate structure; performing an ion implantation process to implant carbon atoms into the cap layer; performing a first etching process to form a recess in the substrate adjacent to two sides of the gate structure; and forming an epitaxial layer in the recess.

### BACKGROUND OF THE INVENTION

1. Field of the Invention

The invention relates to a method for fabricating semiconductor device, and more particularly, to a method of implanting carbon atoms into a cap layer.

2. Description of the Prior Art

A conventional MOS transistor generally includes a semiconductor substrate, such as silicon, a source region, a drain region, a channel positioned between the source region and the drain region, and a gate located above the channel. The gate is composed of a gate dielectric layer, a gate conductive layer positioned on the gate dielectric layer, and a plurality of spacers positioned on the sidewalls of the gate conductive layer. Generally, for a given electric field across the channel of a MOS transistor, the amount of current that flows through the channel is directly proportional to a mobility of the carriers in the channel. Therefore, how to improve the carrier mobility so as to increase the speed performance of MOS transistors has become a major topic for study in the semiconductor field.

The formation of SiGe source/drain regions is commonly achieved by epitaxially growing a SiGe layer adjacent to the spacers within the semiconductor substrate after forming the spacer. In this type of MOS transistor, a uniaxial tensile strain occurs in the epitaxial silicon layer due to the silicon germanium, which has a larger lattice constant than silicon, and, as a result, the band structure alters, and the carrier mobility increases. This enhances the speed performance of the MOS transistor.

In conventional art, at least one etching process, such as a dry etching process or a wet process is conducted to form a recess in the substrate adjacent to two sides of the gate structure before an epitaxial layer is grown from the recess. However, as the gate structure is poorly protected during the growth of epitaxial layer, epitaxial bumps are often grown on the tip of the gate structure and affect the performance and leakage current of the device. Hence, how to improve this problem has become an important task.

### SUMMARY OF THE INVENTION

It is an objective of the present invention to provide a method for fabricating semiconductor device for resolving the aforementioned issue caused by conventional process.

According to a preferred embodiment of the present invention, a method for fabricating semiconductor device is disclosed. The method includes the steps of: providing a substrate, wherein the substrate comprises a gate structure thereon; forming an offset spacer on the sidewall of the gate structure; forming a cap layer to cover the substrate and the gate structure; performing an ion implantation process to implant carbon atoms into the cap layer; performing a first etching process to form a recess in the substrate adjacent to two sides of the gate structure; and forming an epitaxial layer in the recess.

According to another aspect of the present invention, a method for fabricating semiconductor device is disclosed. The method includes the steps of: providing a substrate having a first region and a second region; forming a first gate structure and a second gate structure on the first region and the second region, wherein the sidewall of each of the first gate structure and the second gate structure comprises an offset spacer; forming a cap layer on the substrate, the first gate structure, and the second gate structure; forming a patterned resist on the second region; performing an ion implantation process to implant carbon atoms in the cap layer of the first region; performing a first etching process to form a recess in the substrate adjacent to two sides of the first gate structure; and forming an epitaxial layer in the recess.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 illustrate a method for fabricating a semiconductor device according to a preferred embodiment of the present invention.

### DETAILED DESCRIPTION

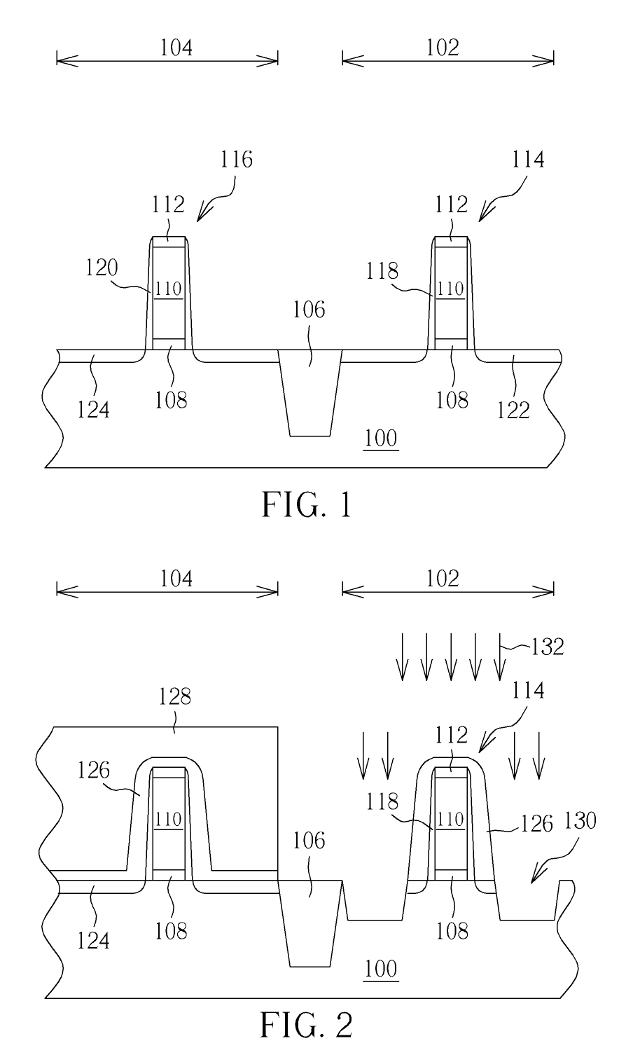

Referring to FIGS. 1-4, FIGS. 1-4 illustrate a method for fabricating a semiconductor device according to a preferred embodiment of the present invention. As shown in FIG. 1, a substrate 100, such as a silicon substrate or a silicon-on-insulator (SOI) substrate is provided. A first region and a second region, such as a PMOS region 102 and a NMOS region 104 are defined on the substrate 100, in which a plurality of shallow trench isolations (STI) 106 are formed in the substrate 100 for isolating the two transistor regions.

A gate dielectric layer, a polysilicon layer, and a hard mask are sequentially formed on the substrate 100, and a pattern transfer process is performed by using a patterned resist (not shown) as mask to partially remove the hard mask, the polysilicon layer, and the gate dielectric layer through single or multiple etching processes to form a first gate structure 114 and a second gate structure 116 on the PMOS region 102 and the NMOS region 104 respectively. Each of the first gate structure 114 and the second gate structure 116 preferably includes a patterned gate dielectric layer 108, polysilicon layer 110, and a hard mask 112.

Next, offset spacers 118, 120 are formed on the sidewall of the first gate structure 114 and the second gate structure 116 and a lightly doped ion implantation process is performed with a rapid thermal anneal of using a temperature of about 930° C. to form a lightly doped drain 122, 124 in the substrate 100 adjacent to two sides of the offset spacers 118, 120.

Next, as shown in FIG. 2, a cap layer 126 is formed on the substrate 100 to cover the first gate structure 114 and the second gate structure 116. A patterned resist 128 is then formed to cover the NMOS region 104, and a dry etching process is conducted to partially remove the cap layer 126 in the PMOS region 102 while forming a recess 130 in the substrate 100 adjacent to two sides of the first gate structure 114. It should be noted that as part of the cap layer 126 on the substrate 100 of the PMOS region 102 is removed while the recess 130 is formed by dry etching, the cap layer 126 on the sidewall of the first gate structure 114 is formed into a temporary spacer. In this embodiment, the cap layer 126 is preferably composed of silicon nitride having a thickness of about 150 +/−100 Angstroms while the thickness of the recess 130 is about 550 +/−200 Angstroms. Next, an ion implantation 132 is conducted to implant carbon atoms into the cap layer 126 of the PMOS region 102 and then removing the patterned resist 128 from the NMOS region 104. Preferably, the energy of the ion implantation for implanting carbon atoms is between 1 KeV to 10 KeV. It should be noted that despite the ion implantation of carbon atoms is conducted before removing the patterned resist 128 from the NMOS region 104, the patterned resist 128 in the NMOS region 104 could also be removed before implanting carbon atoms into the cap layer 126 of both the PMOS region 102 and the NMOS region 104, which is also within the scope of the present invention.

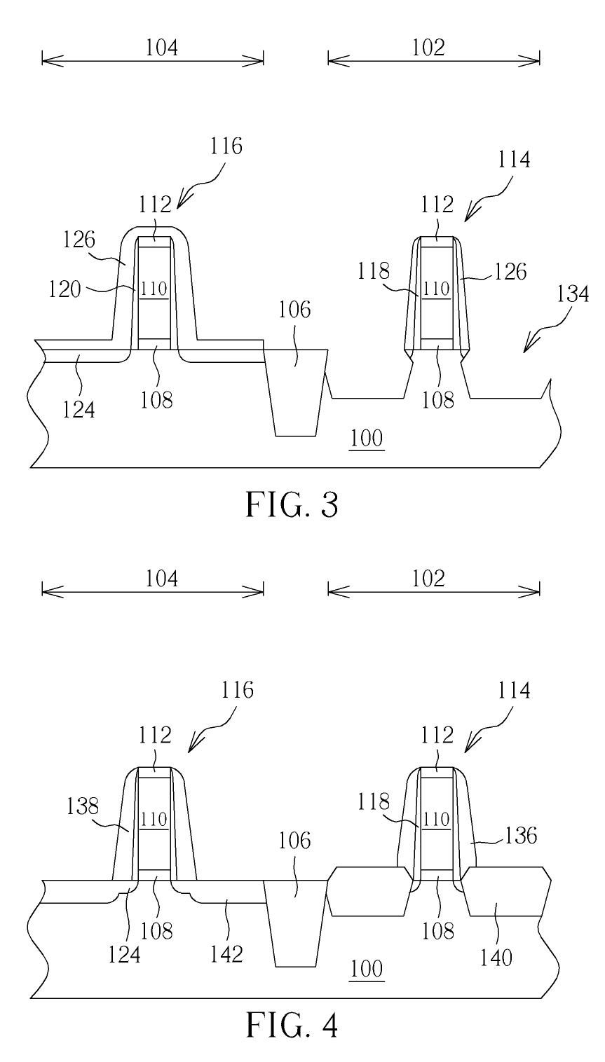

As shown in FIG. 3, a wet etching process is then performed by using etchant such as NH₄OH and amine base chemical, e.g., TMAH to laterally etch the recess 130 by expanding the recess 130 into a substantially diamond shaped recess 134.

It should be noted that even though the aforementioned embodiment is completed by following an order of conducting the dry etching process, implanting carbon atoms, and then performing the wet etching process for forming the recess 134, the present invention could also implant carbon atoms into the cap layer 126 while the patterned resist 128 is disposed on the NMOS region 104 and exposing the PMOS region 102, and then conducting the dry etching process and the wet etching process. This fabrication order is within the scope of the present invention.

Next, as shown in FIG. 4, a pre-clean process could be performed by using diluted hydrofluoric acid or SPM solution containing sulfuric acid, hydrogen peroxide, and deionized water to remove native oxides or other impurities from the surface of the recess 134, and then using a selective epitaxial growth process to fill the recess 134 with an epitaxial layer 140 composed of silicon germanium.

Next, an etching process is performed by using etchant such as phosphoric acid to completely remove the cap layer 126 in both the PMOS region 102 and the NMOS region 104, and a main spacer fabrication is conducted to form a main spacer 136 and 138 on the sidewall of the first gate structure 114 and the second gate structure 116. A patterned resist (not shown) is then formed on the NMOS region 104, and a p-type ion implantation process is carried out to form a source/drain region 140 in the substrate 100 adjacent to two sides of the main spacer 136 in the PMOS region 102. After stripping the patterned resist in the NMOS region 104, another patterned resist (not shown) is formed on the PMOS region 102, and an n-type ion implantation process is conducted to form a source/drain region 142 in the substrate 100 adjacent to two sides of the main spacer 138 in the NMOS region 104. This completes the fabrication of a semiconductor device according to a preferred embodiment of the present invention.

Typically, a cap layer is formed to cover the gate structure in both PMOS region and NMOS region before forming the recess of the epitaxial layer so that the cap layer could be used to protect the gate structures from damage caused by dry etching and wet etching conducted during formation of the recess. However, as conventional art does not apply any treatment to the cap layer deposited, the cap layer is easily damaged during dry etching or wet etching processes thereby exposing part of the gate structure. As a result, epitaxial bumps are formed on the exposed portion of the gate structure during the formation of the epitaxial layer.

Hence, the present invention specifically performs an ion implantation on the cap layer of the region where recess is formed (such as the cap layer of the PMOS region in the aforementioned embodiment) before the wet etching process and before or after the dry etching process conducted for forming the recess of the epitaxial layer. By implanting carbon atoms to strengthen the structure of the cap layer, the cap layer would not be easily damaged during the dry etching or wet etching process conducted thereafter, thereby preventing the formation of epitaxial bumps on the gate structure.

Those skilled in the art will readily observe that numerous modifications and alterations of the device and method may be made while retaining the teachings of the invention.

What is claimed is:

1. A method for fabricating semiconductor device, comprising:
providing a substrate, wherein the substrate comprises a gate structure thereon;
forming an offset spacer on the sidewall of the gate structure;
forming a cap layer to cover the substrate and the gate structure;
performing an ion implantation process to implant carbon atoms into the cap layer;
performing a first etching process to form a recess in the substrate adjacent to two sides of the gate structure; and
forming an epitaxial layer in the recess.

2. The method of claim 1, wherein the gate structure comprises a gate dielectric layer and a gate.

3. The method of claim 1, wherein the first etching process comprises a dry etching process, and the method further comprises performing the dry etching process before the ion implantation process.

4. The method of claim 1, wherein the first etching process comprises a dry etching process, and the method further comprises performing the dry etching process after the ion implantation process.

5. The method of claim 1, further comprising performing a second etching process after the first etching process to expand the recess into a diamond shaped recess.

6. The method of claim 5, wherein the second etching process comprises a wet etching process, and the method comprises performing the ion implantation process before the wet etching process.

7. The method of claim 1, wherein after forming the epitaxial layer further comprises:
removing the cap layer;
forming a main spacer on the sidewall of the offset spacer; and
forming a source/drain region in the substrate adjacent to two sides of the main spacer.

8. The method of claim 1, wherein the semiconductor device comprises a PMOS transistor.

9. The method of claim 1, further comprising performing the etching process to form the recess in the substrate adjacent to two sides of the gate structure while forming the cap layer into a temporary spacer on the sidewall of the gate structure.

10. The method of claim 1, wherein the ion implantation can be processed via beam line implanter, plasma doping implanter, GCIB (Gas cluster ion beam) processing.

11. The method of claim 1, wherein the implant carbon include carbon atom, or carbon containing species consisting of CnHn, n=7, 14.

12. A method for fabricating semiconductor device, comprising:
providing a substrate having a first region and a second region;
forming a first gate structure and a second gate structure on the first region and the second region, wherein the sidewall of each of the first gate structure and the second gate structure comprises an offset spacer;
forming a cap layer on the substrate, the first gate structure, and the second gate structure;
forming a patterned resist on the second region;
performing an ion implantation process to implant carbon atoms in the cap layer of the first region;
performing a first etching process to form a recess in the substrate adjacent to two sides of the first gate structure; and
forming an epitaxial layer in the recess.

13. The method of claim 12, wherein each of the first gate structure and the second gate structure comprises a gate dielectric layer and a gate.

14. The method of claim 12, wherein the first etching process comprises a dry etching process, and the method comprises performing the dry etching process before the ion implantation process.

15. The method of claim 12, wherein the first etching process comprises a dry etching process, and the method comprises performing the dry etching process after the ion implantation process.

16. The method of claim 12, further comprising performing a second etching process after the first etching process to expand the recess into a diamond shaped recess.

17. The method of claim 16, wherein the second etching process comprises a wet etching process, and the method comprises performing the ion implantation process before the wet etching process.

18. The method of claim 12, wherein after forming the epitaxial layer further comprises:
removing the cap layer from the first region and the second region;
forming a main spacer on the sidewall of the first gate structure and the second gate structure; and
forming a source/drain region in the substrate adjacent to two sides of the main spacer.

19. The method of claim 12, wherein the first region comprises a PMOS region and the second region comprises an NMOS region.

20. The method of claim 12, further comprising performing the first etching process to form the recess in the substrate adjacent to two sides of the first gate structure while forming the cap layer into a temporary spacer on the sidewall of the first gate structure.

21. The method of claim 12, wherein the ion implantation can be processed via beam line implanter, plasma doping implanter, GCIB (Gas cluster ion beam) processing.

22. The method of claim 12, wherein the implant carbon include carbon atom, or carbon containing species consisting of CnHn, n=7, 14.
